(19) United States
(12) Patent Application Publication
(10) Pub. No.: US 2024/0067571 A1
(43) Pub. Date: Feb. 29, 2024

(54) MANUFACTURING COMPOSITE ELECTROCERAMICS USING WASTE ELECTROCERAMICS

(71) Applicant: OULUN YLIOPISTO, Oulu (FI)

(72) Inventors: Heli JANTUNEN, OULU (FI); Jari JUUTI, OULU (FI); Mikko NELO, OULU (FI); Tuomo SIPONKOSKI, OULU (FI)

(21) Appl. No.: 18/257,868

(22) PCT Filed: Dec. 15, 2021
(86) PCT No.: PCT/FI2021/050879

§ 371 Date: Jun. 15, 2023

(30) Foreign Application Priority Data
Dec. 16, 2020 (FI) 20206311

(51) Int. Cl. C04B 35/495; C04B 35/622; C04B 35/624; C04B 35/626; C04B 35/645

(52) U.S. Cl. CPC C04B 35/495; C04B 35/62204; C04B 35/624; C04B 35/6261; C04B 35/62655; C04B 35/645; B28B 3/02; C04B 2235/3256; C04B 2235/444; C04B 2235/5427; C04B 2235/604; C04B 2235/606; C04B 2235/656

(57) ABSTRACT

A method for manufacturing composite electroceramics comprises obtaining recycled capacitors, coils, resistors, conductors circuit boards, and/or other recycled electronic components. The components may be grinded into a particles having a particle size below 2 mm, and mixed with NaCl powder or Li₂MoO₄ or other watersoluble ceramic powder having a particle size of 5-200 microns, in a ratio of 10-40 vol-% optionally grinded components, and 60-90 vol-% NaCl powder or Li₂MoO₄ or other ceramic powder. The obtained solids mixture is mixed with aqueous solution of NaCl, Li₂MoO₄ or said other ceramic, in a ratio of 70-90 wt-% solids mixture, and 10-30 wt-% aqueous solution. The obtained homogeneous mass is compressed in a mould for 2-10 min, in room temperature, in a pressure of 100-400 MPa. The compressed mass is removed from the mould, thereby obtaining electroceramic composite material. Alternatively to the use of the water soluble salt an organometallic precursor compound can be used.

### FIELD OF THE INVENTION

The invention relates to composite electroceramics, and particularly to a method for manufacturing composite electroceramics.

### BACKGROUND ART

Ceramic composite materials are used in a wide range of industries, including mining, aerospace, medicine, refinery, food and chemical industries, packaging science, electronics, industrial and transmission electricity, and guided lightwave transmission. Ceramic composite materials may be used for the manufacture of electronic components. Electronic components may be active components such as semiconductors or power sources, passive components such as resistors or capacitors, actuators such as piezoelectric or electromagnetic actuators, or optoelectronic components such as optical switches and/or attenuators. In composite electroceramics manufacturing techniques, aqueous solution of lithium molybdate (LMO, Li₂MoO₄) powder or the like has recently been used as a binder between particles, in contrast to conventional thermally driven sintering or melting assisted mechanism.

An amount of electronic waste is huge worldwide, it is estimated to be more than 40 million ton per year in total. Of this, small electronics accounts for about 4 million ton, of which, for example, ceramic components of mobile phones account for about 16%. Today, only about 20% of the electronic waste is recycled in a controlled way.

### SUMMARY

The following presents a simplified summary of features disclosed herein to provide a basic understanding of some exemplary aspects of the invention. This summary is not an extensive overview of the invention. It is not intended to identify key/critical elements of the invention or to delineate the scope of the invention. Its sole purpose is to present some concepts disclosed herein in a simplified form as a prelude to a more detailed description.

According to an aspect, there is provided the subject matter of the independent claims. Embodiments are defined in the dependent claims.

One or more examples of implementations are set forth in more detail in the description below. Other features will be apparent from the description, and from the claims.

### BRIEF DESCRIPTION OF THE DRAWINGS

In the following the invention will be described in greater detail by means of preferred embodiments with reference to the attached drawings, in which

FIGS. 1 and 2 illustrate schematic microstructure of composite electroceramics manufactured according to an exemplary embodiment, using recycled capacitors;

FIG. 3 illustrates schematic microstructure of composite electroceramic manufactured according to an exemplary embodiment, using recycled capacitors, with additional other ceramic particles/clusters;

FIG. 4 illustrates schematic microstructure of composite electroceramic manufactured according to an exemplary embodiment, using recycled components, with additional other ceramic particles/clusters.

### DETAILED DESCRIPTION OF EMBODIMENTS

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments. Furthermore, words “comprising”, “containing” and “including” should be understood as not limiting the described embodiments to consist of only those features that have been mentioned and such embodiments may contain also features/structures that have not been specifically mentioned.

The amount of electronic waste worldwide totals more than 40 million tonnes per year. Of that, small IT equipment accounts for about 4 million tonnes, of which, for example, the ceramic components of mobile phones account for about 16%. Only about 20% of the electronic waste is recycled in a controlled manner, so there is plenty of raw material available for recycling.

Currently the recycling of electronic waste aims to collect precious metals and use them in the manufacture of new products. The reuse of other materials, such as ceramics, is much more limited due to their chemical stability and very high melting point. Some of the surface mounted components are also three-dimensional structures made of, for example, plastic, metal and ceramic, of which only metals are currently intended to be utilized. Indeed, 80% of electronic waste today ends up either in unspecified recycling, landfills or landfill waste.

Currently, there is no known straightforward, cost-effective and energy-efficient way to recycle electronic waste, even though it is a very highly processed material that has required significant amounts of energy and specific materials to produce.

The present invention utilizes recycling of electronic waste in the production of new materials and components. The present invention encompasses ceramic based electronic waste/discarded discrete components and non-ceramic based electronic waste/discarded discrete components such as semiconductor circuits, surface mount coils, diodes and resistors.

In an embodiment, the method for manufacturing composite electroceramics comprises obtaining recycled capacitors, recycled coils, recycled resistors, recycled conductors, recycled circuit boards, recycled surface mount capacitors, recycled resonators, recycled antennas, and/or other recycled electronic components. The obtained recycled electronic components are optionally grinded into a particle like form having a particle size of less than 2 mm. The recycled electronic components which have optionally been grinded into the particle like form, are mixed with NaCl powder, Li₂MoO₄ powder or powder of other water-soluble ceramic having a particle size of 5-200 μm, preferably above 10 μm, in a volume ratio of 10-40 vol-%, preferably 30 vol-%, recycled electronic components which have optionally been grinded into the particle like form, and 60-90 vol-%, preferably 70 vol-%, said NaCl powder, Li₂MoO₄ powder or powder of other water-soluble ceramic, thereby obtaining a solids mixture. The solids mixture is mixed with saturated aqueous solution of NaCl, saturated aqueous solution of Li₂MoO₄ or saturated aqueous solution of said other water-soluble ceramic, in a weight ratio of 70-90 wt-%, preferably 80 wt-% solids mixture, and 10-30 wt-%, preferably 20 wt %, the saturated aqueous solution of NaCl, saturated aqueous solution of Li₂MoO₄ or saturated aqueous solution of said other water-soluble ceramic, thereby obtaining a homogeneous mass. The obtained homogeneous mass is compressed in a mould for 2-10 min, preferably 10 min, in room temperature, and in a pressure of 100-400 MPa, preferably 150-300 MPa, more preferably 250 MPa, thereby obtaining a compressed homogeneous mass. The compressed homogeneous mass is removed from the mould, thereby obtaining electroceramic composite material.

The aqueous solution of NaCl may be saturated aqueous solution of NaCl, the aqueous solution of Li₂MoO₄ may be saturated aqueous solution of Li₂MoO₄, and/or the aqueous solution of said other water-soluble ceramic may be saturated aqueous solution of said other water-soluble ceramic. Alternatively, the aqueous solution of NaCl may be non-saturated or almost saturated aqueous solution of NaCl, the aqueous solution of Li₂MoO₄ may be non-saturated or almost saturated aqueous solution of Li₂MoO₄, and/or the aqueous solution of said other water-soluble ceramic may be non-saturated or almost saturated aqueous solution of said other water-soluble ceramic.

The obtained electroceramic composite material may be dried in a temperature of 10-150° C., preferably 110° C., for 0.3-48 hours, preferably 10-48 hours, to remove water from the material. The drying may be carried out in the mould during and/or after the compressing, in a desiccator, in an oven, and/or in room air.

Additionally, in an embodiment, a method is described herein for manufacturing composite electroceramics, the method comprising obtaining recycled capacitors, recycled coils, recycled resistors, recycled conductors, recycled circuit boards, and/or other recycled electronic components. The obtained recycled electronic components are optionally grinded into a particle like form having a particle size of less than 2 mm. The recycled electronic components which have optionally been grinded into the particle like form, are mixed with a binder composition, in a weight ratio of 10-30 wt-%, preferably 25 wt-%, recycled electronic components which have optionally been grinded into the particle like form, and 70-90 wt-%, preferably 75 wt-%, said binder composition, thereby obtaining a homogeneous mass, wherein said binder composition contains at least one metal oxide powder and at least one organometallic precursor compound in a weight ratio of from 60:10 to 70:10, preferably 65:10. The homogeneous mass is compressed in a mould for 10-60 min, preferably 30-60 min, in a temperature of 80-200° C., preferably 160° C., and in a pressure of 100-400 MPa, preferably 150-300 MPa, more preferably 250 MPa, to remove solvent liquid from the homogeneous mass, thereby obtaining a compressed homogeneous mass. The compressed homogeneous mass contained in the mould is further compressed for 10-60 min, preferably 60 min, in a temperature of 250-400° C., preferably 350° C., and in a pressure of 100-400 MPa, preferably 150-300 MPa, more preferably 250 MPa, allowing the organometallic precursor compound to react to form metal oxide(s) in the compressed homogeneous mass. Thereafter the compressed homogeneous mass contained is cooled in the mould to a temperature of below 100° C. The compressed homogeneous mass is removed from the mould, thereby obtaining electroceramic composite material.

The compressed homogeneous mass contained in the mould may be cooled to the temperature of below 100° C., e.g. 80° C. or below, e.g. for at least 30 min, while allowing the pressure in the mould to decrease.

The at least one organometallic precursor compound may be gel-like organometallic precursor compound capable of forming metal oxide(s) or other organometallic compound capable of forming metal oxide(s), or a mixture thereof capable of forming metal oxide(s), and/or a gel-like sol-gel reaction product capable of forming metal oxide(s) under the influence of heat.

The metal oxide may be TiO₂, PZT, BaₓSr₁₋ₓTiO₃, BaTiO₃, Al₂O₃, KNBNNO, ferrite material, titanate material, niobate material, nitride material, carbide material, and/or perovskite material.

The recycled electronic components which have optionally been grinded into the particle like form may have a multimodal particle size, having particles with two or more different particle sizes, with a particle size of less than 2 mm, and/or said NaCl powder, Li₂MoO₄ powder or powder of other water-soluble ceramic may have a multimodal particle size, having particles with two or more different particle sizes.

10-40 vol %, preferably 30 vol %, of the content of the produced electroceramic composite material may originate from the recycled electronic components, the rest 60-90 vol-%, preferably 70 vol-%, being NaCl, Li₂MoO₄ or other water-soluble ceramic, or metal oxide.

The recycled electronic components may have dielectric, ferroelectric, ferromagnetic, paraelectric, paramagnetic, piezoelectric and/or pyroelectric properties, and/or the recycled electronic components may include resistors, conductors, capacitors, coils, sensors, actuators, high frequency passive devices, energy storage components, energy harvesting components, tuning elements, transformers, optical switches, antennas, optical attenuators, batteries, light emitting diodes, active components, integrated circuits, and/or electrical interconnections.

Said other water-soluble ceramic may be one or more of Na₂Mo₂O₇, K₂Mo₂O₇, (LiBi)_{0.5}MoO₄, KH₂PO₄, Li₂WO₄, Mg₂P₂O₇, V₂O₅, LiMgPO₄, and/or any other water-soluble ceramic.

Electroceramic composite produced by the method may have a recycled materials content of 10-40 vol %, preferably 30 vol %, said recycled materials content originating from the recycled electronic components, wherein NaCl, Li₂MoO₄ or other water-soluble ceramic or metal oxide based binder content of the electroceramic composite may be 60-90 vol-%, preferably 70 vol-%, said binder content forming a binder phase in the electroceramic composite, binding the recycled materials content of the electroceramic composite. The electroceramic composite may be dielectric, ferroelectric, ferromagnetic, paraelectric, paramagnetic, piezoelectric, pyroelectric composite, and/or electromagnetic metamaterial composite. Electronic component is also disclosed, comprising said electroceramic composite. The electroceramic composite may be used in the manufacture of an electronic component and/or optoelectronic component. The electronic component may be a resistor, conductor, capacitor, coil, sensor, actuator, high frequency passive device, energy storage component, energy harvesting component, tuning element, transformer, antenna, battery, light emitting diode, active component, integrated circuit, and/or electrical circuit board.

The present invention enables manufacturing electroceramic composites from electronic waste. The properties of the material to be produced may be controlled by selecting a suitable electronic waste fraction based on its material properties and structure. The produced electroceramic composites may be used to prepare electrical components (antennas, resonators, transducers) and also for RF interference protection, electrical insulation, and many other similar applications.

The present invention utilizes electronic waste materials in the manufacture of electroceramic composites for various electrical applications. Various materials may be used as fillers for composites. In the present invention, electronic components discarded in quality control may be used as filler material in the electroceramic composite to be produced. In this case the electronic waste components used may contain various different materials, including, for example, electrical connections, internal electrodes, dielectrics, etc. Depending on the external dimensions of the components to be manufactured, electronic waste components with an external dimension of less than 2 mm may be used as such, but larger pieces are crushed to a process-friendly size before use for the manufacture.

Components removed from discarded circuit boards (discarded in quality control or after use) may also be used as composite filler material in the present invention. Again, depending on the external dimensions of the components to be manufactured, waste circuit board components with an external dimension of less than 2 mm may be used as such, but larger pieces are crushed to a process-friendly size before use for the manufacture.

It is also possible to use crushed electronic waste as such, as composite filler material. In this case the components used may contain various different materials, including, for example, electrical connections, internal electrodes, dielectrics, etc. Yet again, depending on the external dimensions of the components to be manufactured, electronic waste components with an external dimension of less than 2 mm may be used as such, but larger pieces are crushed to a process-friendly size before use for the manufacture.

The ceramic-forming binder solution may be an aqueous solution of a water-soluble metal oxide or salt (e.g. Li₂MoO₄, LMO), or alternatively a precursor of an organometallic compound which, by means of elevated pressure and/or heating, forms metal oxide. The binder may be added in a liquid form to the electroceramic waste powder where its function is to form a bond between the electroceramic particles by means of pressure and/or heating. The temperature range used is exceptionally low, for example, the temperature may be room temperature, or in case of precursor 80-200° C., preferably 160° C./250-400° C., preferably 350° C.

The electrical properties of the composites may be adjusted by using different types of electroceramic waste components and/or raw materials as starting material. Electronic waste components such as, for example, surface mount coils, capacitors, resistors, resonators and antennas, containing ceramic material and metal(s). Metal and plastic parts of the electronic waste may also be used to adjust the properties (e.g. relative permittivity) of the electroceramics composite to be produced. The applications of the manufactured materials may be, for example, attenuators of electromagnetic signals, telecommunication components (resonators, filters, circuit boards, antenna substrates), sensors and interference shielding, or electromagnetic metamaterials.

The invention makes it possible to produce high-performance electroceramic composites with very low energy consumption from basically free or even negative cost (waste treatment costs can be avoided) waste, and from a binder that has a very reasonable purchase price. In the present invention, a new type of reuse of electronic waste is disclosed with low raw material costs, where it is possible to utilize new waste fractions for the manufacture of composite electroceramics. The present invention is advantageous for the electronics industry as it enables electronics waste material recycling and as it enables to enhance sustainable development.

The present invention provides the use of various electronic waste fractions directly in the manufacture of new electroceramic components or elements, for example, for the protection against electromagnetic interference. In the present invention, electronic waste may be utilized in various ways as raw material for the production of electroceramic composite. Waste fractions formed by defective components discarded in the components production may be utilized as raw material, such that discarded surface joint components may be crushed or used as such (depending on their size) as a filler in the electroceramic composite material. For example, recycled capacitors embedded inside the produced electroceramic composite material increase the permittivity of the composite material. The composite material may be prepared using a binder comprising, for example, water-soluble metal oxide. The amount of filler material (waste material) in the composite material to be prepared may be varied depending on the purpose of the composite. The binder or binder solution forming the ceramic or metal salt comprises an aqueous solution of a water-soluble ceramic or salt (e.g. Li₂MoO₄, LMO), or alternatively a precursor of an organometallic compound which reacts with pressure and heating to form particles bonding the metal together. The manufacturing temperature is exceptionally low, preferably room temperature (if water-soluble ceramic or salt is used), or e.g. 250-400° C., preferably 350° C. (if a precursor of an organometallic compound is used). In the method, the filler may be mixed with, for example, LMO to form a powder mixture which is wetted with a small amount of water to form a homogeneous mass. The homogeneous mass is compressed into a solid, wherein the residual water is removed by evaporation.

The waste fraction may be added as such or it may be crushed, and the magnetic properties of the waste material-based filler material may optionally be adjusted with e.g. MnZn ferritic ceramic powder. Instead of a water-soluble ceramic/salt, a precursor of an organometallic compound may be used which during the process reacts and is converted into a ceramic salt. The filler material, i.e. the waste material particles, may also be coated with a ceramic/salt/organometallic precursor compound.

Recycling of electronic waste may involve recovering precious metals from circuit boards and components, with less attention being paid to other materials. The electronic waste may contain large amounts of components with interesting electrical properties. By removing and crushing these components to a particle like form having a grain size suitable for the process of the present invention, they may be used as fillers in various electroceramic composites. For example, a high metal content in the particle like material increases the dielectric loss tangent of the material at high frequencies, so that the manufactured composite may be utilized in interference protection. Small amounts of metal, when appropriately distributed in the microstructure of the composite, in turn have a permittivity-increasing effect which may be utilized, for example, in the miniaturization of antennas and capacitors. Correspondingly, plastics crushed into the desired size reduces the permittivity of the prepared electroceramic composite, whereby its suitability for e.g. very high frequency (>50 GHz) antenna circuits is improved. Various properties may be obtained by using a specific combination of recycled capacitors/coils/plastics/metal/semiconductors, as such or crushed, in the ceramic matrix material.

It is also possible to use recycled/discarded electronic surface mount components as an organized structure in the electroceramic composite. Surface mount components, as such or crushed to a particle like form having a desired particle size, may be stacked to form an organized structure in order to prepare the composite. For example, recycled coils may be placed on polymer sheet templates to form the organized structure of the composite. In this way electroceramic composite materials with a negative refractive index (metamaterial) may be obtained. The obtained metamaterials enable, for example, to direct electromagnetic radiation.

In one embodiment, the recycled electronic components which have optionally been grinded into the particle like form, are mixed with the NaCl powder, Li₂MoO₄ powder or powder of said other water-soluble ceramic having a particle size of 5-200 μm, preferably above 10 μm, in a volume ratio of up to 90 vol-% recycled electronic components which have optionally been grinded into the particle like form, and at least 10 vol-% said NaCl powder, Li₂MoO₄ powder or powder of other water-soluble ceramic, to obtain the solids mixture in the manufacture process.

In one embodiment, the capacitors, coils, resistors, conductors, circuit boards, and/or other electronic components to be used as filler material in the electroceramic composite, may be new/unused electronic components, such as new/unused capacitors, coils, resistors, conductors, circuit boards. For example, they may be components that have not been sold for some reason.

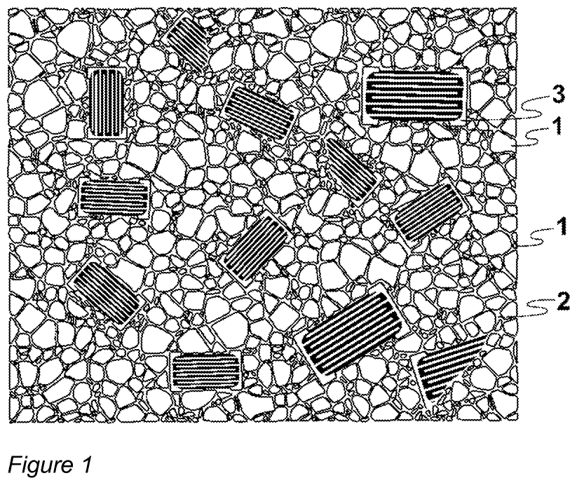

FIG. 1 illustrates schematic microstructure of composite electroceramic (not in scale) manufactured according to an exemplary embodiment, using recycled capacitors. FIG. 1 shows ceramic binder material 1, grain boundaries 2 of the ceramic binder material 1, and recycled electronic capacitors 3 (broken/unbroken).

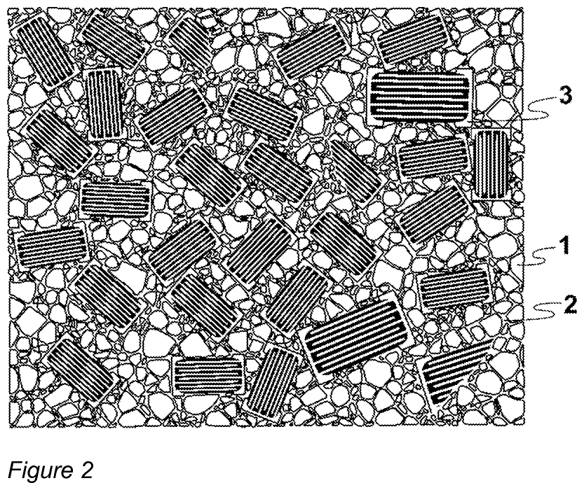

FIG. 2 illustrates schematic microstructure of composite electroceramic (not in scale) manufactured according to an exemplary embodiment, using recycled capacitors, with a higher capacitor load ratio. FIG. 2 shows ceramic binder material 1, grain boundaries 2 of the ceramic binder material 1, and recycled electronic capacitors 3 (broken/unbroken).

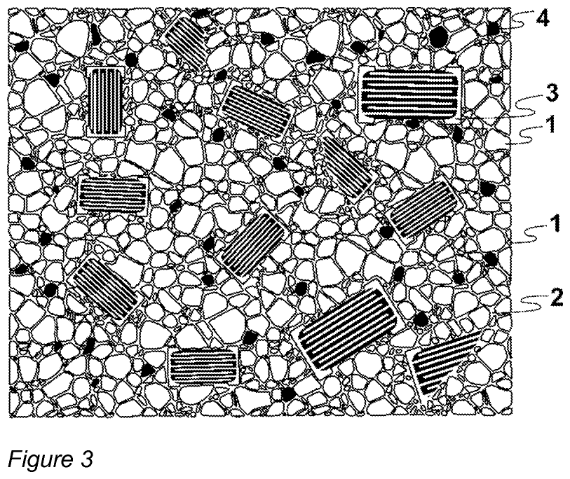

FIG. 3 illustrates schematic microstructure of composite electroceramic (not in scale) manufactured according to an exemplary embodiment, using recycled capacitors, with additional other ceramic particles/clusters. FIG. 3 shows ceramic binder material 1, grain boundaries 2 of the ceramic binder material 1, recycled electronic capacitors 3 (broken/unbroken), and particles/clusters 4 of other ceramic, carbon and/or metal.

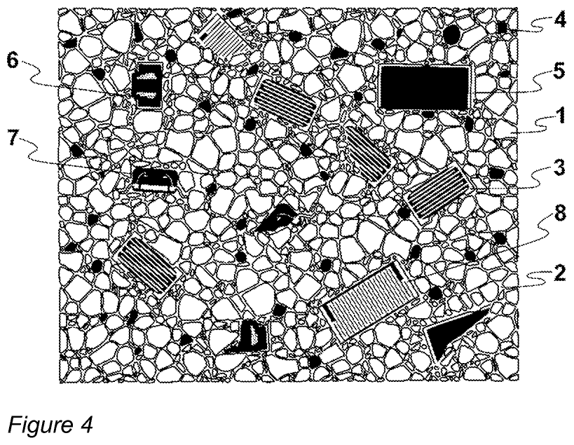

FIG. 4 illustrates schematic microstructure of composite electroceramic (not in scale) manufactured according to an exemplary embodiment, using various recycled components, with additional other ceramic particles/clusters. FIG. 4 shows ceramic binder material 1, grain boundaries 2 of the ceramic binder material 1, recycled electronic capacitors 3 (broken/unbroken), partiIles/clusters 4 of other ceramic, carbon or metal, antennas 5 (broken/unbroken), inductors 6 (broken/unbroken), integrated circuits 7 (broken/unbroken), and meander line antennas/inductors 8 (broken/unbroken).

### Example 1

The method was tested by preparing electroceramic composite using whole surface mount capacitors as such (170 mg) and crushed surface mount capacitors (838 mg). Using about 70 vol-% Li₂MoO₄ as binder and about 30 vol-% mixture of crushed and intact capacitors gave a relative permittivity of 18 and a dielectric loss tangent of 0.0028 measured at 1 MHz frequency of the electric current, for the prepared electroceramic composite material. These material properties are suitable, for example, as substrate material for various telecommunication components. Thus a mixture of crushed and intact capacitors were used as the waste fraction, while using LMO as a binder. Dense samples of the material were compressed as described above to prepare electroceramic composite material for the testing. The relative permittivity increased to about four times of that of pure lithium molybdate.

It will be obvious to a person skilled in the art that, as the technology advances, the inventive concept can be implemented in various ways. The invention and its embodiments are not limited to the examples described above but may vary within the scope of the claims.

1. A method for manufacturing composite electroceramics, the method comprising
obtaining recycled capacitors, recycled coils, recycled resistors, recycled conductors, recycled circuit boards, and/or other recycled electronic components;
optionally grinding the obtained recycled electronic components into a particle like form having a particle size of less than 2 mm;
mixing the recycled electronic components which have optionally been grinded into the particle like form, with NaCl powder, Li₂MoO₄ powder or powder of other water-soluble ceramic having a particle size of 5-200 μm, preferably above 10 μm, in a volume ratio of 10-40 vol-%, preferably 30 vol-%, recycled electronic components which have optionally been grinded into the particle like form, and 60-90 vol-%, preferably 70 vol-%, said NaCl powder, Li₂MoO₄ powder or powder of other water-soluble ceramic, thereby obtaining a solids mixture;
mixing the solids mixture with aqueous solution of NaCl, aqueous solution of Li₂MoO₄ or aqueous solution of said other water-soluble ceramic, in a weight ratio of 70-90 wt-%, preferably 80 wt-% solids mixture, and 10-30 wt-%, preferably 20 wt-%, the aqueous solution of NaCl, aqueous solution of Li₂MoO₄ or aqueous solution of said other water-soluble ceramic, thereby obtaining a homogeneous mass;
compressing the obtained homogeneous mass in a mould for 2-10 min, preferably 10 min, in room temperature, and in a pressure of 100-400 MPa, preferably 150-300 MPa, more preferably 250 MPa, thereby obtaining a compressed homogeneous mass; and
removing the compressed homogeneous mass from the mould, thereby obtaining electroceramic composite material.

2. A method as claimed in claim 1, the method comprising drying the obtained electroceramic composite material in a temperature of 10-150° C., preferably 110° C., for 0.3-48 hours, preferably 10-48 hours, to remove water from the material,
wherein the drying is carried out in the mould during and/or after the compressing, in a desiccator, in an oven, and/or in room air.

3. A method as claimed in claim 1, wherein
the aqueous solution of NaCl is saturated aqueous solution of NaCl,
the aqueous solution of Li₂MoO₄ is saturated aqueous solution of Li₂MoO₄, and/or
the aqueous solution of said other water-soluble ceramic is saturated aqueous solution of said other water-soluble ceramic.

4. A method for manufacturing composite electroceramics, the method comprising
obtaining recycled capacitors, recycled coils, recycled resistors, recycled conductors, recycled circuit boards, and/or other recycled electronic components;
optionally grinding the obtained recycled electronic components into a particle like form having a particle size of less than 2 mm;
mixing the recycled electronic components which have optionally been grinded into the particle like form, with a binder composition, in a weight ratio of 10-30 wt-%, preferably 25 wt-%, recycled electronic components which have optionally been grinded into the particle like form, and 70-90 wt-%, preferably 75 wt-%, said binder composition, thereby obtaining a homogeneous mass, wherein said binder composition contains at least one metal oxide powder and at least one organometallic precursor compound in a weight ratio of from 60:10 to 70:10, preferably 65:10;
compressing the homogeneous mass in a mould for 10-60 min, preferably 30-60 min, in a temperature of 80-200° C., preferably 160° C., and in a pressure of 100-400 MPa, preferably 150-300 MPa, more preferably 250 MPa, to remove solvent liquid from the homogeneous mass, thereby obtaining a compressed homogeneous mass;
further compressing the compressed homogeneous mass contained in the mould for 10-60 min, preferably 60 min, in a temperature of 250-400° C., preferably 350° C., and in a pressure of 100-400 MPa, preferably 150-300 MPa, more preferably 250 MPa, allowing the organometallic precursor compound to react to form metal oxide(s) in the compressed homogeneous mass; and
thereafter cooling the compressed homogeneous mass contained in the mould to a temperature of below 100° C., and removing the compressed homogeneous mass from the mould, thereby obtaining electroceramic composite material.

5. A method as claimed in claim 4, wherein the at least one organometallic precursor compound is
gel-like organometallic precursor compound capable of forming metal oxide(s) or other organometallic compound capable of forming metal oxide(s), or a mixture thereof capable of forming metal oxide(s), and/or
a gel-like sol-gel reaction product capable of forming metal oxide(s) under the influence of heat.

6. A method as claimed in claim 4, wherein the metal oxide is TiO₂, PZT, BaₓSr₁₋ₓTiO₃, BaTiO₃, Al₂O₃, KNBNNO, ferrite material, titanate material, niobate material, nitride material, carbide material, and/or perovskite material.

7. A method as claimed in claim 1, wherein
the recycled electronic components which have optionally been grinded into the particle like form have a multimodal particle size, having particles with two or more different particle sizes, with a particle size of less than 2 mm, and/or
said NaCl powder, Li₂MoO₄ powder or powder of other water-soluble ceramic has a multimodal particle size, having particles with two or more different particle sizes.

8. A method as claimed in claim 1, wherein
10-40 vol %, preferably 30 vol %, of the content of the electroceramic composite material originates from the recycled electronic components,
the rest 60-90 vol-%, preferably 70 vol-%, being NaCl, Li₂MoO₄ or other water-soluble ceramic, or metal oxide.

9. A method as claimed in claim 1, wherein
the recycled electronic components have dielectric, ferroelectric, ferromagnetic, paraelectric, paramagnetic, piezoelectric and/or pyroelectric properties, and/or
the recycled electronic components include resistors, conductors, capacitors, coils, sensors, actuators, high frequency passive devices, energy storage components, energy harvesting components, tuning elements, transformers, optical switches, antennas, optical attenuators, batteries, light emitting diodes, active components, integrated circuits, and/or electrical interconnections.

10. A method as claimed in claim 1, wherein said other water-soluble ceramic is one or more of Na₂Mo₂O₇, K₂Mo₂O₇, (LiBi)_{0.5}MoO₄, KH₂PO₄, Li₂WO₄, Mg₂P₂O₇, V₂O₅, LiMgPO₄, and/or any other water-soluble ceramic.

11. Electroceramic composite produced by the method as claimed in claim 1, wherein
a recycled, optionally grinded, electronic components content of the electroceramic composite is 10-40 vol %, preferably 30 vol %, said recycled, optionally grinded, electronic components content originating from the recycled capacitors, recycled coils, recycled resistors, recycled conductors, recycled circuit boards, and/or other recycled electronic components, and having a particle size of less than 2 mm, and
NaCl, Li₂MoO₄ or other water-soluble ceramic or metal oxide based binder content of the electroceramic composite is 60-90 vol-%, preferably 70 vol-%, said binder content forming a binder phase in the electroceramic composite, binding the recycled, optionally grinded, electronic components content of the electroceramic composite.

12. Electroceramic composite as claimed in claim 11, wherein the electroceramic composite is dielectric composite, ferroelectric composite, ferromagnetic composite, paraelectric composite, paramagnetic composite, piezoelectric composite, pyroelectric composite, and/or electromagnetic metamaterial composite.

13. Electronic component comprising the electroceramic composite as claimed in claim 11.

14. Use of the electroceramic composite as claimed in claim 11 in the manufacture of an electronic component and/or optoelectronic component.

15. Electronic component as claimed in claim 11, wherein the electronic component is a resistor, conductor, capacitor, coil, sensor, actuator, high frequency passive device, energy storage component, energy harvesting component, tuning element, transformer, antenna, battery, light emitting diode, active component, integrated circuit, and/or electrical circuit board.

16. A method as claimed in claim 4, wherein
the recycled electronic components which have optionally been grinded into the particle like form have a multimodal particle size, having particles with two or more different particle sizes, with a particle size of less than 2 mm, and/or
said NaCl powder, Li₂MoO₄ powder or powder of other water-soluble ceramic has a multimodal particle size, having particles with two or more different particle sizes.

17. A method as claimed in claim 4, wherein
10-40 vol %, preferably 30 vol %, of the content of the electroceramic composite material originates from the recycled electronic components,
the rest 60-90 vol-%, preferably 70 vol-%, being NaCl, Li₂MoO₄ or other water-soluble ceramic, or metal oxide.

18. A method as claimed in claim 4, wherein
the recycled electronic components have dielectric, ferroelectric, ferromagnetic, paraelectric, paramagnetic, piezoelectric and/or pyroelectric properties, and/or
the recycled electronic components include resistors, conductors, capacitors, coils, sensors, actuators, high frequency passive devices, energy storage components, energy harvesting components, tuning elements, transformers, optical switches, antennas, optical attenuators, batteries, light emitting diodes, active components, integrated circuits, and/or electrical interconnections.

19. A method as claimed in claim 4, wherein said other water-soluble ceramic is one or more of Na₂Mo₂O₇, K₂Mo₂O₇, (LiBi)_{0.5}MoO₄, KH₂PO₄, Li₂WO₄, Mg₂P₂O₇, V₂O₅, LiMgPO₄, and/or any other water-soluble ceramic.

20. Electroceramic composite produced by the method as claimed in claim 4, wherein
a recycled, optionally grinded, electronic components content of the electroceramic composite is 10-40 vol %, preferably 30 vol %, said recycled, optionally grinded, electronic components content originating from the recycled capacitors, recycled coils, recycled resistors, recycled conductors, recycled circuit boards, and/or other recycled electronic components, and having a particle size of less than 2 mm, and
NaCl, Li₂MoO₄ or other water-soluble ceramic or metal oxide based binder content of the electroceramic composite is 60-90 vol-%, preferably 70 vol-%, said binder content forming a binder phase in the electroceramic composite, binding the recycled, optionally grinded, electronic components content of the electroceramic composite.

21. Electroceramic composite as claimed in claim 20, wherein the electroceramic composite is dielectric composite, ferroelectric composite, ferromagnetic composite, paraelectric composite, paramagnetic composite, piezoelectric composite, pyroelectric composite, and/or electromagnetic metamaterial composite.

22. Electronic component comprising the electroceramic composite as claimed in claim 20.

23. Use of the electroceramic composite as claimed in claim 20 in the manufacture of an electronic component and/or optoelectronic component.

24. Electronic component as claimed in claim 22, wherein the electronic component is a resistor, conductor, capacitor, coil, sensor, actuator, high frequency passive device, energy storage component, energy harvesting component, tuning element, transformer, antenna, battery, light emitting diode, active component, integrated circuit, and/or electrical circuit board.

25. The use of claim 23, wherein the electronic component is a resistor, conductor, capacitor, coil, sensor, actuator, high frequency passive device, energy storage component, energy harvesting component, tuning element, transformer, antenna, battery, light emitting diode, active component, integrated circuit, and/or electrical circuit board.
